(19) United States
(12) Patent Application Publication
(10) Pub. No.: US 2026/0324264 A1
(43) Pub. Date: Oct. 15, 2026

(54) Display Substrate, Preparation Method and Display Apparatus

(71) Applicants: Beijing BOE Technology Development Co., Ltd., Beijing (CN); BOE Technology Group Co., Ltd., Beijing (CN)

(72) Inventors: Youngsuk SONG, Beijing (CN); Yuhang LU, Beijing (CN)

(21) Appl. No.: 18/836,766

(22) PCT Filed: Nov. 30, 2023
(86) PCT No.: PCT/CN2023/135630

§ 371 Date: Aug. 8, 2024

(51) Int. Cl. H10K 59/80; H10K 59/12; H10K 59/122

(52) U.S. Cl. CPC H10K 59/879; H10K 59/1201; H10K 59/122

(57) ABSTRACT

A display substrate, a preparation method and a display apparatus are provided. The display substrate includes a glass base substrate (10) and a composite layer (15) and a planarization layer (23) disposed in a direction away from the glass base substrate (10). The glass base substrate (10) includes a first lens region (10c) at an end face close to the composite layer (15). The composite layer (15) and/or the planarization layer (23) include a second lens region (23a) at an end face away from the glass base substrate (10). An orthographic projection of the second lens region (23a) on the glass base substrate (10) at least partially overlaps an orthographic projection of the first lens region (10c) on the glass base substrate (10).

### CROSS-REFERENCE TO RELATED APPLICATION

The present application is a U.S. National Phase Entry of International Application No. PCT/CN2023/135630 having an international filing date of Nov. 30, 2023, contents of which are incorporated herein by reference.

### TECHNICAL FIELD

The present disclosure relates to, but is not limited to, the field of display technologies, and in particular to a display substrate, a preparation method and a display apparatus.

### BACKGROUND

An Organic Light Emitting Diode (OLED) and a Quantum dot Light Emitting Diode (QLED) are active light emitting display devices and have advantages such as self-luminescence, wide viewing angle, high contrast ratio, low power consumption, very high response speed, lightness and thinness, flexibility, and low cost. At present, a light emitting efficiency of a display substrate is low.

### SUMMARY

The following is a summary of subject matters described herein in detail. This summary is not intended to limit the protection scope of claims.

An embodiment of the present disclosure provides a display substrate including a glass base substrate and a composite layer and a planarization layer disposed in a direction facing away from the glass base substrate.

The glass base substrate includes a first lens region at an end face close to the composite layer, and the composite layer and/or the planarization layer includes a second lens region at an end face away from the glass base substrate.

An orthographic projection of the second lens region on the glass base substrate at least partially overlaps an orthographic projection of the first lens region on the glass base substrate.

In some exemplary embodiments, a plurality of first microlenses are arranged in the first lens region, and a first microlens is provided as a first arc-shaped surface recessed toward a side of the glass base substrate away from the composite layer.

A plurality of second microlenses are arranged in the second lens region, and a second microlens is provided as a second arc-shaped surface recessed towards the glass base substrate.

In some exemplary embodiments, at least one of the first microlenses and the second microlenses has the same structure and size.

In some exemplary embodiments, the composite layer is made of an inorganic-organic mixed resin having a refractive index of 1.5 to 1.9.

In some exemplary embodiments, a diameter of a cross section of the first arc-shaped surface in a direction parallel to the glass base substrate is set to be from 1 micron to 50 microns.

The first arc-shaped surface is set to have a maximum size of 0.5 microns to 25 microns in a direction perpendicular to the glass base substrate.

In some exemplary embodiments, a light filter layer is further included. The light filter layer is arranged to overlay an end face of the planarization layer close to the glass base substrate. A refractive index of the planarization layer is set to be greater than a refractive index of the light filter layer.

A refractive index of the composite layer is set to be greater than a refractive index of the glass base substrate.

In some exemplary embodiments, a first electrode layer, a pixel definition layer, a light emitting layer, and a second electrode layer are further included.

The first electrode layer, the light emitting layer and the second electrode layer are stacked sequentially in a direction away from the glass base substrate, the first electrode layer is located on a side of the planarization layer away from the glass base substrate, and the first electrode layer is provided as a light-transmitting electrode.

The pixel definition layer encloses a plurality of pixel openings, and the light emitting layer is located within the pixel openings.

The second electrode layer is configured to reflect light passing through the pixel definition layer toward the glass base substrate.

In some exemplary embodiments, an orthographic projection of the pixel definition layer on the glass base substrate at least overlaps an orthographic projection of the first lens region or/and the second lens region on the glass base substrate.

In some exemplary embodiments, the second electrode layer is configured to enclose a plurality of first grooves with notches facing the glass base substrate.

The pixel definition layer includes a plurality of pixel defining units arranged at intervals in a direction parallel to the glass base substrate, the plurality of pixel defining units each enclosing a pixel opening.

The light emitting layer includes a plurality of light emitting members. The light emitting members and the pixel defining units are arranged in one-to-one correspondence and are both located in the first grooves.

In some exemplary embodiments, the planarization layer includes a plurality of planarization units. The plurality of planarization units are arranged in one-to-one correspondence with the plurality of pixel defining units and located within the first grooves. The plurality of planarization units are each provided with the second lens region on a side away from the glass base substrate.

In some exemplary embodiments, a light filter layer is further included. The light filter layer is positioned on a side of the planarization layer close to the glass base substrate.

The light filter layer includes a plurality of light filters arranged at intervals in a direction parallel to the glass base substrate. The light filters are arranged in one-to-one correspondence with the pixel defining units and located in the first grooves.

In some exemplary embodiments, a plurality of first lens regions are provided. The light filters are arranged in one-to-one correspondence with the first lens regions. An orthographic projection of the first lens regions on the glass base substrate is located within an orthographic projection of the light filters on the glass base substrate.

In some exemplary embodiments, a drive circuit layer is further included. The drive circuit layer is located between the glass base substrate and the first electrode layer.

The second electrode layer includes groove portions and overlay portions arranged alternately in a direction parallel to the glass base substrate, the groove portions are each arranged in a groove shape, the groove portions enclose the first grooves, and the overlay portion are overlaid on a surface of the drive circuit layer away from the glass base substrate.

In some exemplary embodiments, the groove portions each include a groove side wall configured to be annular in a direction parallel to the glass base substrate and a groove bottom wall configured to close an end of the groove side wall away from the glass base substrate.

A circumferential surface of a pixel defining unit in a direction parallel to the glass base substrate is provided as a first end face.

A circumferential surface of a planarization unit in the direction parallel to the glass base substrate is provided as a second end face.

A circumferential surface of a light filter in the direction parallel to the glass base substrate is provided as a third end face.

The first end face, the second end face and the third end face are configured to be arranged sequentially in a direction perpendicular to the glass base substrate.

The groove side wall is configured to overlay the first end face, the second end face and the third end face.

The groove bottom wall is configured to overlay the pixel defining unit and an end face of the light emitting members away from the glass base substrate.

In some exemplary embodiments, a drive circuit assembly and a light shielding layer are further included. The drive circuit assembly is located between the planarization layer and the composite layer.

The first electrode layer includes a plurality of first electrode units, and the first electrode units are arranged in the first grooves.

The drive circuit assembly includes a connection electrode, and a first electrode unit connects the connection electrode through a via.

The light shielding layer is provided as a high reflectivity metal film, and the light shielding layer is located on the first electrode layer and/or the connection electrode and arranged corresponding to the via to block light directly irradiated toward the glass base substrate from the via.

In some exemplary embodiments, the light shielding layer is configured to overlay an end face of the connection electrode facing the via, and an orthographic projection of the light shielding layer on the glass base substrate is configured to at least partially overlap an orthographic projection of the via on the glass base substrate.

In some exemplary embodiments, the first electrode unit includes a via connection portion located within the via, and the light shielding layer is configured to overlay an end face of the via connection portion away from the glass base substrate.

In some exemplary embodiments, the via is configured to penetrate through the planarization layer and the light filter layer, the first electrode unit is configured to overlay at least a portion of a hole wall of the via, and the pixel definition layer extends into the via.

An embodiment of the present disclosure provides a preparation method applied to the above-mentioned display substrate, including: forming a plurality of first microlenses on the glass base substrate, wherein the plurality of first microlenses are arranged in the first lens region, and a first microlens is provided as a first arc-shaped surface recessed toward an end face of the glass base substrate away from the composite layer; and forming a plurality of second microlenses on the composite layer and/or the planarization layer, wherein the plurality of second microlenses are arranged in the second lens region, and a second microlens is provided as a second arc-shaped surface recessed towards the glass base substrate.

An embodiment of the present disclosure provides a display apparatus including the display substrate described above.

Other aspects may be comprehended after the drawings and the detailed description are read and understood.

### BRIEF DESCRIPTION OF DRAWINGS

The drawings are used to provide understanding of technical solutions of the present disclosure, and form a part of the specification. The drawings, together with the embodiments of the present disclosure, are used to explain the technical solutions of the present disclosure, and do not form limitations on the technical solutions of the present disclosure.

FIG. 1 is a schematic diagram of a structure of a display apparatus.

FIG. 2 is a schematic diagram of a planar structure of a display substrate.

FIG. 3 is a schematic diagram of a cross-sectional structure of a display substrate.

FIG. 4 is a schematic diagram of a display substrate of the present exemplary embodiment;

FIG. 5 is a schematic cross-sectional view taken along an A-A direction of FIG. 4;

FIG. 6 is a schematic cross-sectional view taken along a B-B direction of FIG. 4;

FIG. 7 is a schematic view of the glass base substrate of FIG. 5;

FIG. 8 is a partially enlarged schematic diagram at D of FIG. 7;

FIG. 9 is a partially enlarged schematic diagram at C of FIG. 5;

FIG. 10 is a partial schematic view of the display substrate shown in FIG. 6;

FIG. 11 is a schematic cross-sectional view of yet another display substrate of the present exemplary embodiment;

FIG. 12 is a schematic cross-sectional view of another display substrate of the present exemplary embodiment;

FIG. 13 is a schematic cross-sectional view of yet another display substrate of the present exemplary embodiment;

FIG. 14 is a schematic cross-sectional view of another display substrate of the present exemplary embodiment;

FIG. 15 is a schematic diagram of a first preparation of the display substrate shown in FIG. 5;

FIG. 16 is a schematic diagram of a second preparation of the display substrate shown in FIG. 5;

FIG. 17 is a schematic diagram of a third preparation of the display substrate shown in FIG. 5;

FIG. 18 is a schematic diagram of a fourth preparation of the display substrate shown in FIG. 5;

FIG. 19 is a schematic diagram of a fifth preparation of the display substrate shown in FIG. 5;

FIG. 20 is a partially enlarged schematic diagram at E in FIG. 19;

FIG. 21 is a schematic diagram of a sixth preparation of the display substrate shown in FIG. 5;

FIG. 22 is a schematic diagram of a seventh preparation of the display substrate shown in FIG. 5;

FIG. 23 is a schematic diagram of an eighth preparation of the display substrate shown in FIG. 5; and

FIG. 24 is a schematic diagram of a ninth preparation of the display substrate shown in FIG. 5.

Reference signs are described as follows.

| | | |
|---|---|---|
| 10- Glass base substrate; | 11- Shielding layer; | 12- First metal layer; |
| 13- First microlens; | 14- First arc-shaped surface; | 15- Composite layer; |
| 16- First buffer layer; | 17- Interlayer insulating layer; | 18- Drive circuit assembly; |
| 19- Connection electrode; | 20- Drive circuit layer; | 21- Light filter layer; |
| 22- First through hole; | 23-Planarization layer; | 24- Second through hole; |
| 25- Third through hole; | 26- Second microlens; | 27- Second arc-shaped surface; |
| 28- Filter layer pattern; | 29- Planarization layer pattern; | 30- Light emitting structure layer; |
| 31- Light filter; | 32- Via; | 33- First electrode pattern; |
| 34- First electrode layer; | 35- Pixel definition layer pattern; | 36- Pixel definition layer; |
| 37- Pixel opening. | 38- Light emitting layer; | 39- Light emitting member; |
| 40- Encapsulation structure layer; | 41- First member; | 42- Second electrode layer; |
| 43- Encapsulation film; | 44- Cover plate; | 45- Planarization unit; |
| 46- Pixel defining unit; | 47- First electrode unit; | 48- First groove; |
| 49- Groove portion; | 50- Overlay portion; | 51- First end face; |
| 52- Second end face; | 53- Third end face; | 54- Light shielding layer; |
| 55- Via connection portion; | 56- First light shielding portion; | 57- Second light shielding portion; |
| 58- Fourth end face; | 59- Groove side wall; | 60- Groove bottom wall. |

### DETAILED DESCRIPTION

To make the objectives, technical solutions, and advantages of the present disclosure clearer, the embodiments of the present disclosure will be described in detail below with reference to the drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate according to a direction in which each constituent element is described. Therefore, appropriate replacements based on situations are allowed, and the positional relationships are not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, in the specification the “source electrode” and the “drain electrode” are interchangeable, and the “source terminal” and the “drain terminal” are interchangeable.

In the specification, an “electrical connection” includes connection of constituent elements through an element with a certain electrical action. An “element with a certain electrical action” is not particularly limited as long as electrical signals may be sent and received between the connected constituent elements. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, hexagon and the like in this specification are not strictly defined, and they may be approximate triangle, rectangle, trapezoid, pentagon, hexagon and the like. There may be some small deformations caused by tolerance, and there may be chamfer, arc edge, deformation, etc.

In an embodiment of the present disclosure, “about” refers to a value that is not strictly limited, and a value within a range of process and measurement error is allowed.

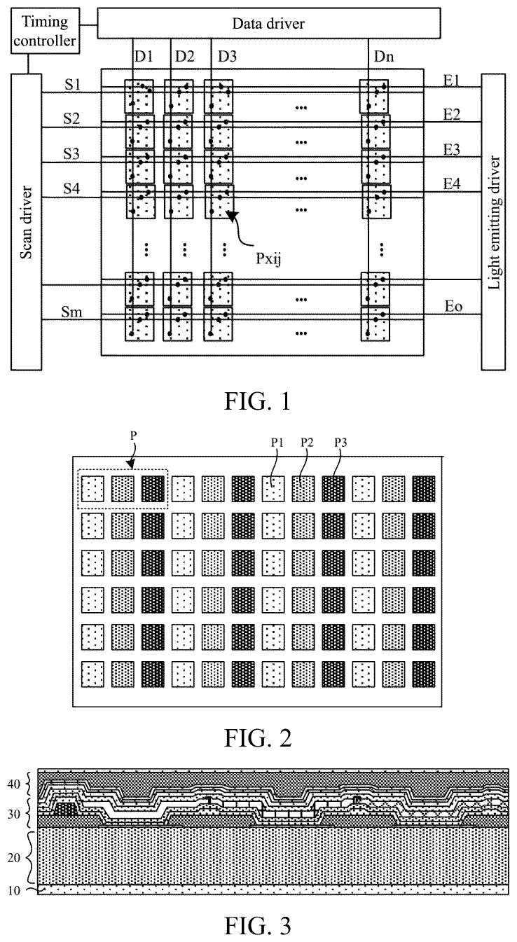

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include multiple sub-pixels Pxij, wherein i and j may be natural numbers. At least one sub-pixel Pxij may include a circuit unit and a light emitting device connected to the circuit unit, and the circuit unit may include a pixel drive circuit which is connected with a scan signal line, a light emitting signal line and a data signal line. In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate a data voltage to be provided to the data signal lines D1, D2, D3, . . . , and Dn by using the grayscale value and the control signal that are received from the timing controller. For example, the data driver may sample the grayscale value by using the clock signal and apply a data voltage corresponding to the grayscale value to the data signal lines D1 to Dn by taking a unit row as a unit, wherein n may be a natural number. The scan driver may generate a scan signal to be provided to the scan signal lines S1, S2, S3, . . . , and Sm by receiving the clock signal and the scan start signal and the like from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may generate an emission signal to be provided to the light emitting signal lines E1, E2, E3, . . . , and Eo by receiving a clock signal, an emission stop signal or the like from the timing controller. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be disposed on the display substrate.

FIG. 2 is a schematic diagram of a planar structure of a display substrate. As shown in FIG. 2, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting device. The circuit unit may at least include a pixel drive circuit, the pixel drive circuit is connected to a scan signal line, a light emitting signal line, and a data signal line respectively, and the pixel drive circuit is configured to receive a data voltage transmitted by the data signal line and output a corresponding current to the light emitting device under control of the scan signal line and the light emitting signal line. The light emitting device in each sub-pixel is connected to a pixel drive circuit of a sub-pixel where the light emitting device is located, and is configured to emit light with corresponding brightness in response to a current output by the pixel drive circuit of the sub-pixel where the light emitting device is located.

In an exemplary implementation, the first sub-pixel P1 may be a red sub-pixel (R) emitting red light, the second sub-pixel P2 may be a blue sub-pixel (B) emitting blue light, and the third sub-pixel P3 may be a green sub-pixel (G) emitting green light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a “W” shape etc., which is not limited here in the present disclosure.

In an exemplary implementation, a pixel unit may include four sub-pixels, and the four sub-pixels may be arranged in a manner to stand side by side horizontally, in a manner to stand side by side vertically, or in a manner of a square, which is not limited here in the present disclosure.

FIG. 3 is a schematic diagram of a cross-sectional structure of a display substrate. As shown in FIG. 3, in a plane perpendicular to the display substrate, the display substrate may include a drive circuit layer 20 arranged on a glass base substrate 10, a light emitting structure layer 30 arranged on a side of the drive circuit layer 20 away from the glass base substrate 10, and an encapsulation structure layer 40 arranged on a side of the light emitting structure layer 30 away from the glass base substrate 10. In some possible implementations, the display substrate may include another film layer, such as a touch structure layer, which is not limited here in the present disclosure.

In an exemplary implementation, the glass base substrate 10 may be a flexible base substrate, or may be a rigid base substrate. The drive circuit layer 20 may include a plurality of circuit units, each of which may at least include a pixel drive circuit composed of a plurality of transistors and a storage capacitor. The light emitting structure layer 30 may include a plurality of light emitting devices, and each light emitting device may at least include an anode, a pixel definition layer, an organic emitting layer, and a cathode. The anode is connected with the pixel drive circuit, the organic emitting layer is connected with the anode, the cathode is connected with the organic emitting layer, and the organic emitting layer emits light of a corresponding color under drive of the anode and the cathode. The encapsulation structure layer 40 may include a first encapsulation layer, a second encapsulation layer, and a third encapsulation layer which are stacked. The first encapsulation layer and the third encapsulation layer may adopt an inorganic material, the second encapsulation layer may adopt an organic material, and the second encapsulation layer is disposed between the first encapsulation layer and the third encapsulation layer to form an inorganic material/organic material/inorganic material stack structure, which can ensure that external water vapor cannot enter the light emitting structure layer 30, but is not limited to this. For example, the first encapsulation layer, the second encapsulation layer, and the third encapsulation layer are all inorganic materials or are all organic materials.

At present, in an OLED display apparatus without a light efficiency improvement structure, only 20% of the light emitted by the light emitting device can emit light from the front side of the picture, which means that 80% of the light cannot be emitted from an end face on a side of the glass base substrate away from the light emitting device and disappears, resulting in low luminous efficiency. For the bottom-emitting light emitting device, although the related OLED display apparatus has a light efficiency improvement structure so that more light is emitted from the end face on a side of the glass base substrate away from the light emitting device and the luminous efficiency can be improved to a certain extent, the improvement effect is not ideal.

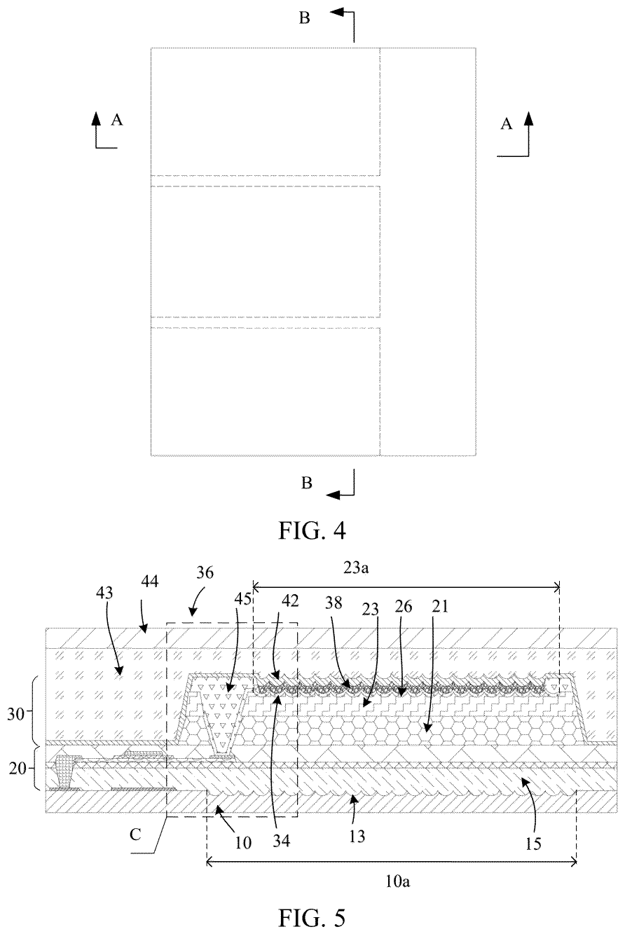

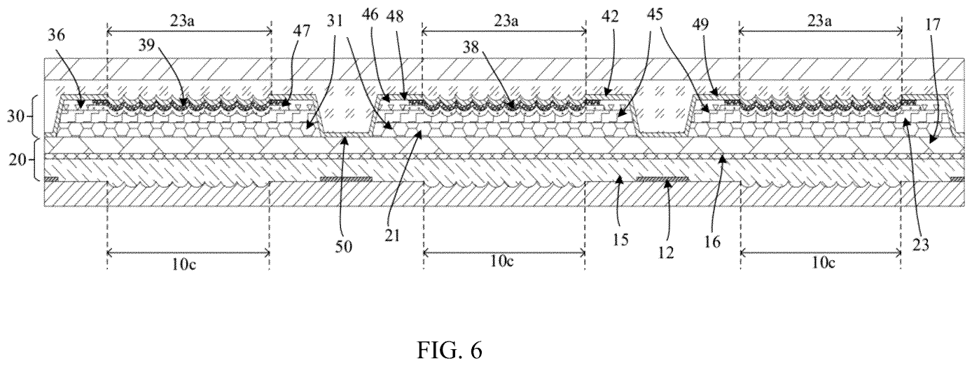

FIG. 4 is a schematic diagram of a display substrate of the present exemplary embodiment, FIG. 5 is a schematic cross-sectional diagram taken along an A-A direction in FIG. 4, and FIG. 6 is a schematic cross-sectional diagram taken along a B-B direction in FIG. 4. An embodiment of the present disclosure provides a display substrate, as shown in FIGS. 4 to 6. The display substrate may include a glass base substrate 10 and a composite layer 15 and a planarization layer 23 disposed in a direction facing away from the glass base substrate 10. The glass base substrate 10 may include a first lens region 10c at an end face close to the composite layer 15, and the composite layer 15 and/or the planarization layer 23 may include a second lens region 23a at an end face away from the glass base substrate 10. An orthographic projection of the second lens region 23a on the glass base substrate 10 is configured to at least partially overlap the first lens region 10c. Thus, the display substrate includes at least two layers of microlens array (MLA), so that more light can be emitted from the display substrate, the brightness of the display substrate can be improved, the luminous efficiency can be improved, and the power consumption can be reduced when the preset light intensity is reached.

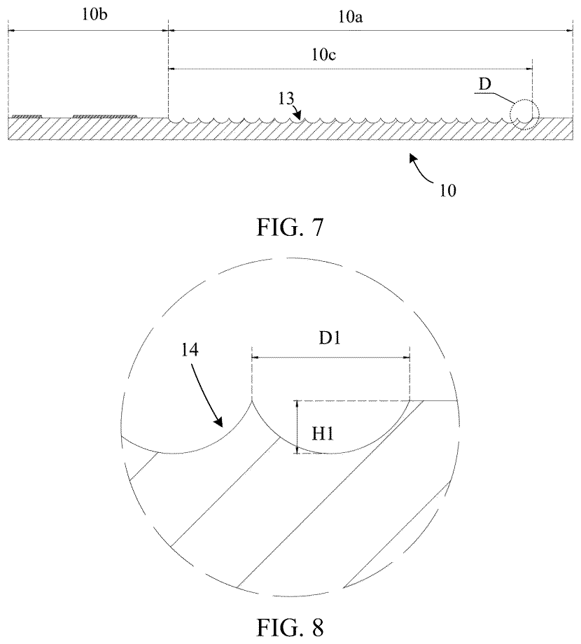

FIG. 7 is a schematic diagram of the glass base substrate in FIG. 5, and FIG. 8 is a partially enlarged schematic diagram at D in FIG. 7. In some exemplary embodiments, as shown in FIGS. 7 and 8, a material of the glass base substrate 10 may be light-transmitting glass, a refractive index of the glass base substrate 10 may be less than 1.55, and the display substrate of this example may emit light on a side having the glass base substrate 10. A surface on a side of the glass base substrate 10 includes a light emitting region 10a and a circuit region 10b. The light emitting region 10a may include a first lens region 10c. A plurality of first microlenses 13 are uniformly arranged in the first lens region 10c, and the plurality of first microlenses 13 are arranged in an array to form a microlens array (MLA). In an exemplary embodiment, the plurality of first microlenses 13 in the first lens region 10c are of the same structure and size. Microlens arrays can converge light to increase brightness and viewing angle, and have the characteristics of miniaturization, lightweight, and array and the like, and can also improve color performance.

In some exemplary embodiments, as shown in FIGS. 5, 6, 7 and 8, a first microlens 13 may be a first arc-shaped surface 14 recessed on a surface of the glass base substrate 10 facing the composite layer 15, and the first arc-shaped surface 14 may be recessed towards a surface of the glass base substrate 10 away from the composite layer 15, forming an arc-shaped groove structure. A height of the first arc-shaped surface 14 may be set as a maximum distance between the first arc-shaped surface 14 and a surface of the glass base substrate 10 facing the composite layer 15, that is, a maximum size H1 of the first arc-shaped surface 14 in a direction perpendicular to the glass base substrate 10. A value of H1 may be 0.5 μm (micron) to 25 μm (micron). In an exemplary embodiment, a cross section of the first arc-shaped surface 14 in a direction parallel to the glass base substrate 10 is circular, and a maximum diameter of the cross section of the first arc-shaped surface 14 in a direction parallel to the glass base substrate 10 may be D1, and a value of D1 may be 1 μm (micron) to 50 μm (micron). The glass base substrate 10 has a plurality of light emitting regions 10a arranged at intervals, the circuit region 10b may separate the plurality of light emitting regions 10a, and the size and arrangement of the first microlenses 13 in the plurality of light emitting regions 10a may be consistent.

In some exemplary embodiments, as shown in FIGS. 5 to 7, the composite layer 15 may be overlaid on the glass base substrate 10, and a material of the composite layer 15 may be an organic-inorganic mixed resin, which is a light-transmitting material and a mixture of inorganic and organic substances. The organic-inorganic mixed resin contains silicon (Si), oxygen (O), and nitrogen (N), and has good heat resistance and can withstand high temperatures from 300° C. to 500° C. The composite layer 15 is a mixture of inorganic and organic materials, so that the composite layer 15 has the functions of a planarization layer and a buffer layer at the same time. A refractive index of the composite layer 15 may be 1.5 to 1.9, and a refractive index of the composite layer 15 may be changed by adjusting the ratio of the content of oxygen (O) and nitrogen (N) in the organic-inorganic mixed resin, while a refractive index of the composite layer 15 may be greater than a refractive index of the glass base substrate 10. A plane of the composite layer 15 away from the glass base substrate 10 is parallel to the glass base substrate 10, and protruding portions of a surface of the composite layer 15 close to the glass base substrate 10 fill arc-shaped grooves formed by recesses of the first arc-shaped surface 14. In addition, the glass base substrate 10 also includes a first metal layer 12, which is arranged corresponding to the circuit region 10b. The circuit region 10b is at least partially overlaid by the first metal layer 12. The first metal layer 12 may be an alloy made of copper (Cu), aluminum (Al), silver (Ag), titanium (Ti), molybdenum (Mo) or low-resistance metal. A part of the first metal layer 12 may be a light shielding plate to block light from emitting, and another part of the first metal layer 12 may be SD or VDD wiring. A plurality of light emitting regions 10a may be provided, and a first metal layer 12 may be arranged in the circuit region 10b separating the plurality of light emitting regions 10a.

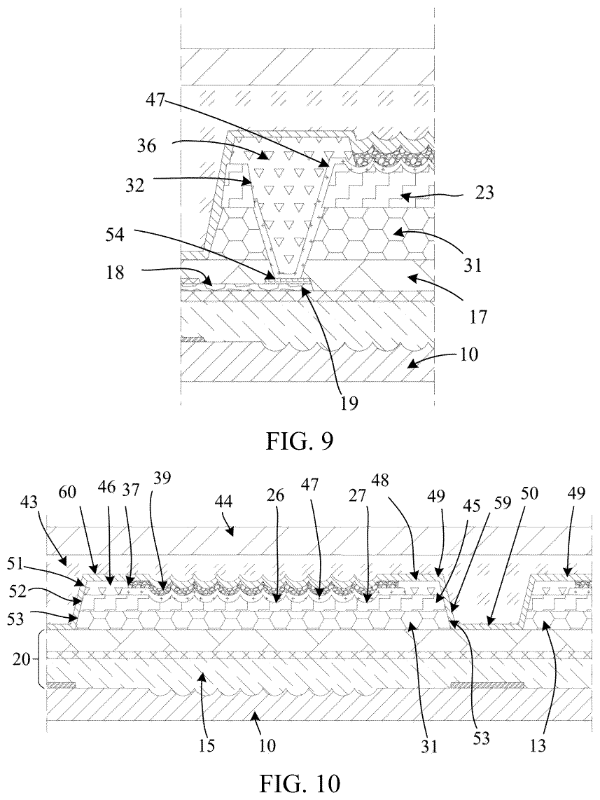

FIG. 9 is a partially enlarged schematic view at C of FIG. 5. In some exemplary embodiments, as shown in FIGS. 5 and 10, the display substrate further includes a first buffer layer 16, an interlayer insulating layer (Inter-Layer Dielectric/passivating film, ILD/PVX) 17 and a drive circuit assembly 18. The first metal layer 12, the composite layer 15, the first buffer layer 16, the interlayer insulating layer (ILD/PVX) 17 and the drive circuit assembly 18 may constitute a drive circuit layer 20 which is overlaid on the glass base substrate 10. The composite layer 15, the first buffer layer 16, and the interlayer insulating layer (ILD/PVX) 17 are sequentially stacked in a direction away from the glass base substrate 10. The drive circuit assembly 18 is located between the glass base substrate 10 and the interlayer insulating layer (ILD/PVX) 17 and is electrically connected to the connecting first metal layer 12 through a via structure. The interlayer insulating layer (ILD/PVX) 17 overlays the drive circuit assembly 18.

FIG. 10 is a partial schematic view of the display substrate in FIG. 6. In some exemplary embodiments, as shown in FIGS. 5, 6 and 10, the display substrate further includes a first electrode layer 34, a pixel definition layer 36, a light emitting layer 38, a second electrode layer 43, and a light filter layer 21. The first electrode layer 34, the light emitting layer 38, and the second electrode layer 43 may be stacked in sequence in a direction away from the glass base substrate 10, the first electrode layer 34 may be located on a side of the planarization layer 23 away from the glass base substrate 10, and the first electrode layer 34 may be a light-transmitting electrode. The pixel definition layer 36 can enclose a plurality of pixel openings 37. The light emitting layer 38 is located within the pixel openings 37. The material of the pixel definition layer 36 is provided as a light-transmitting material. The second electrode layer 43 may be a high-reflectivity electrode. The second electrode layer 43 may reflect light passing through the pixel definition layer 36 toward the glass base substrate 10. The first electrode layer 34, the pixel definition layer 36, the light emitting layer 38, the second electrode layer 43, the planarization layer 23, and the light filter layer 21 may constitute the light emitting structure layer 30.

In some exemplary embodiments, as shown in FIGS. 5, 6 and 10, the second electrode layer 43 is configured to enclose a plurality of first grooves 48 with notches facing the glass base substrate 10, and the second electrode layer 43 includes a plurality of groove portions 49 and a plurality of overlay portions 50 alternately arranged in a direction parallel to the glass base substrate 10. The groove portions 49 may be groove-shaped, and the overlay portions 50 are overlaid on a surface of the drive circuit layer 20 away from the glass base substrate 10. A groove portion 49 includes a groove side wall 59 and a groove bottom wall 60, the groove side wall 59 may be configured to be annular in a direction parallel to the glass base substrate 10, and the groove bottom wall 60 may be parallel to the glass base substrate 10 and may close an end of the groove side wall 59 away from the glass base substrate 10. The second electrode layer 43 may be a high-reflectivity electrode, and the second electrode layer 43 may be a cathode.

In some exemplary embodiments, as shown in FIGS. 5, 6 and 10, the pixel definition layer 36 includes a plurality of pixel defining units 46 arranged at intervals in a direction parallel to the glass base substrate. The plurality of pixel defining units 46 all enclose the pixel openings 37 such that the pixel definition layer 36 has a plurality of independent pixel defining units 46. The number of pixel defining units 46 coincides with the number of the pixel openings 37 in an exemplary embodiment. The light emitting layer 38 includes a plurality of light emitting members 39. The light emitting members 39 and the pixel defining units 46 can be arranged in one-to-one correspondence, that is, each light emitting member 39 is arranged in a pixel opening 37 of the corresponding pixel defining unit 46, and at the same time, the whole formed by each light emitting member 39 and the corresponding pixel defining unit 46 is in a first groove 48, so that the light emitting members 39 and the first grooves 48 are arranged in one-to-one correspondence. The light emitting member 39 may emit white light under power supply conditions. As a result, the first groove 48 enclosed by the second electrode layer 43 provides a mounting space for the light emitting member 39 and the pixel defining unit 46, and separates adjacent light emitting members 39 and separates adjacent pixel defining units 46. The light emitted by the light emitting members 39 can only be irradiated toward the glass base substrate 10 through the notches of the first grooves 48, and a plurality of light emitting members 39 share a cathode.

In some exemplary embodiments, as shown in FIGS. 5, 6 and 10, the first electrode layer 34 includes a plurality of first electrode units 47 arranged at intervals in a direction parallel to the glass base substrate 10. The planarization layer 23 includes a plurality of planarization units 45 arranged at intervals in the direction parallel to the glass base substrate 10. The light filter layer 21 includes a plurality of light filters 31 arranged at intervals in the direction parallel to the glass base substrate 10. The first electrode units 47, the planarization units 45 and the light filters 31 can all be in one-to-one correspondence with and within the first grooves 48. The light filters 31, the planarization units 45 and the first electrode units 47 are sequentially stacked in a direction away from the glass base substrate 10. As a result, the first grooves 48 enclosed by the second electrode layer 43 also provide a mounting space for the first electrode units 47, the planarization units 45 and the light filters 31, separates adjacent first electrode units 47, separates adjacent planarization units 45, and separates adjacent light filters 31. The light emitted by the light emitting members 39 passes through the planarization units 45 and passes through the light filters 31, and then is irradiated toward the glass base substrate 10 through the notches of the first grooves 48.

In some exemplary embodiments, as shown in FIGS. 5, 6, and 10, the light filter layer 21 may filter light to filter white light into light of a preset color. The light filter layer 21 may include a red light filter, a green light filter, or a blue light filter, i.e. the plurality of light filters 31 may be red light filters, green light filters, or blue light filters. In some exemplary embodiments, the size and arrangement of the first microlenses 13 in the light emitting region 10a corresponding to the different light filters 31 are different, so that the sub-pixels of different colors are differentiated to meet the requirements of the light extraction intensity of the sub-pixels of different colors. For example, each light emitting member 39 emits white light. The plurality of light filters 31 can be divided into three types, a first light filter 31 can filter white light into red light, a second light filter 31 can filter white light into green light, and a third light filter 31 can filter white light into blue light. The sizes and arrangements of the first microlenses 13 corresponding to the three light filters 31 are different, so that the intensities of red light, green light, and blue light are different, and the requirements for light extraction intensity of the sub-pixels of different colors are met. An orthographic projection of a pixel opening 37 on the glass base substrate 10 may be located within an orthographic projection of the light filter layer 21 on the glass base substrate 10, and another part of the end face of the drive circuit layer 20 away from the glass base substrate 10 is overlaid by the overlay portions 50 of the second electrode layer 43. A refractive index of the planarization layer 23 is set to be greater than that of the light filter layer 21. The first electrode unit 47 may be made of a light-transmitting electrode material. The first electrode unit 47 may be an anode. Each of the light emitting members 39 uses the corresponding first electrode unit 47 as an anode, but each of the light emitting members uses the second electrode layer as a cathode to form a common cathode. The planarization unit 45 may be provided as a light-transmitting material. Thereby, after the white light emitted by the light emitting member 39 penetrates the first electrode unit 47 and the planarization unit 45, it is filtered by the light filter 31 into a light of a preset color, and then penetrates the drive circuit layer 20 and the glass base substrate 10 to be emitted from the display substrate.

In some exemplary embodiments, as shown in FIGS. 5, 6 and 10, a surface of the planarization layer 23 away from the glass base substrate 10 may include a second lens region 23a. An orthographic projection of the second lens region 23a on the glass base substrate 10 is located within the first lens region 10c. The planarization layer 23 may have a plurality of second lens regions 23a. Each planarization unit 45 has one second lens region 23a. The second lens regions 23a and the first lens regions 10c are in one-to-one correspondence. A plurality of second microlenses 26 are uniformly arranged in the second lens region 23a, and the plurality of second microlenses 26 are arranged in an array to form a microlens array. A second microlens 26 may be a second arc-shaped surface 27 recessed on a surface of the planarization layer 23 away from the glass base substrate 10, and the second arc-shaped surface 27 may be recessed toward a surface of the planarization layer 23 away from the light emitting structure layer 30, forming an arc-shaped groove structure. The structures, sizes, and arrangements of the second arc-shaped surface 27 and the first arc-shaped surface 14 are consistent, but are not limited to this. For example, the second arc-shaped surface 27 and the first arc-shaped surface 14 are inconsistent in at least one of the structure, size, and arrangement. An orthographic projection of the pixel definition layer 36 on the glass base substrate 10 at least overlaps an orthographic projection of the first lens region 10c or/and the second lens region 23a on the glass base substrate 10. Both the orthographic projections of the first lens region 10c and the second lens region 23a on the glass base substrate 10 are located within an orthographic projection of the light filter layer 21 on the glass base substrate 10.

In some exemplary embodiments, a surface of the planarization layer 23 away from the glass base substrate 10 may include a second lens region 23a. The glass base substrate 10 may include a plurality of first lens regions 10c at an end face close to the composite layer 15. The second lens regions 23a and the first lens regions 10c are in one-to-one correspondence. A second arc-shaped surface 27 of a second lens region 23a and a first arc-shaped surface 14 of a first lens region 10c are of different dimensions. A dimension of the first arc-shaped surface 14 in a direction perpendicular to the glass base substrate 10 is larger than that of the second arc-shaped surface 27 in the direction perpendicular to the glass base substrate 10, and an orthographic projection area of the single first arc-shaped surface 14 on the glass base substrate 10 is larger than an orthographic projection area of the single second arc-shaped surface 27 on the glass base substrate 10.

In some exemplary embodiments, as shown in FIGS. 5, 6, and 10, a circumferential end face of the pixel defining unit 46 is a first end face 51. The first end face 51 is an outer surface of the pixel defining unit 46 in a direction parallel to the glass base substrate 10, that is, each first end face 51 is an end face of the pixel defining unit 46 facing an adjacent pixel defining unit 46. A circumferential end face of the planarization unit 45 is a second end face 52. The second end face 52 is an outer surface of the planarization unit 45 in a direction parallel to the glass base substrate 10, that is, the second end face 52 is an end face of each planarization unit 45 facing an adjacent planarization unit 45. A circumferential end face of the light filter 31 is a third end face 53. The third end face 53 is an outer surface of the light filter 31 in a direction parallel to the glass base substrate 10, that is, the third end face 53 is an end face of each light filter 31 facing an adjacent light filter 31. The light emitting members 39, the pixel defining units 46, the first electrode units 47, the planarization units 45 and the light filters 31 may all be in one-to-one correspondence with and within the first grooves 48, so that the groove side walls 59 of the groove portions 49 in the second electrode layer 43 overlay the first end faces 51, the second end faces 52 and the third end faces 53, thereby preventing color mixing, that is, preventing cross-mixing of light filtered by adjacent light filters 31. As a result, the second electrode layer 43 forms a reflection structure overlaying the first end face 51, the second end face 52, and the third end face 53. The reflection structure can reflect the large-angle light emitted by the sub-pixels, so that the light is converged, and the light extraction efficiency is improved.

In some exemplary embodiments, as shown in FIG. 9, the drive circuit assembly 18 includes a connection electrode 19 to which a first electrode unit 47 of the first electrode layer 34 is electrically connected through a via 32. The connection electrode 19 may be provided with an opaque light shielding layer 54 corresponding to the via 32, so as to block the light directly irradiated toward the glass base substrate 10 from the via 32, and prevent the white light directly irradiated toward the glass base substrate 10 from the via 32 from mixing with light with other colors through the light filter 31. The light shielding layer 54 may be a high reflectivity metal film, and the light shielding layer 54 may overlay an end face of the connection electrode 19 facing the via 32. The via 32 extends in a direction perpendicular to the glass base substrate 10. The via 32 penetrates through the planarization layer 23 and the light filter layer 21, and extends to the connection electrode 19, and the pixel definition layer 36 overlays the via 32.

In some exemplary embodiments, as shown in FIGS. 5 and 6, the display substrate further includes an encapsulation structure layer 40 including an encapsulation film 43 and a cover plate 44. The cover plate 44 is mounted on a side of the encapsulation film 43 away from the glass base substrate 10. The encapsulation film 43 may be one or more layers of inorganic or organic thin films. The encapsulation film 43 overlays an end face of the light emitting structure layer 30 away from the glass base substrate 10. The encapsulation film 43 can prevent water and oxygen from entering the display substrate, providing a good water-oxygen isolation characteristic for the display substrate. The cover plate 44 is overlaid on a side of the encapsulation film 43 away from the glass base substrate 10, and the cover plate can provide protection for the display substrate.

In some exemplary embodiments, the display substrate of the present example may emit light from the bottom. The glass base substrate 10 is located at the bottom of the display substrate. Under the condition of power supply of a light emitting member 39, light directly irradiated toward the glass base substrate 10 by the light emitting member 39 can be filtered by the light filter 31 and then irradiated toward the glass base substrate 10 through a notch of a first groove 48. The light irradiated toward the pixel defining unit 36 by the light emitting member 39 will be reflected to a side of the glass base substrate 10 by the second electrode layer after passing through the pixel defining unit 36, so that light emitted from the light emitting structure layer 20 is more, the brightness and light emitting efficiency can be improved, and the power consumption can be reduced when the preset brightness is reached.

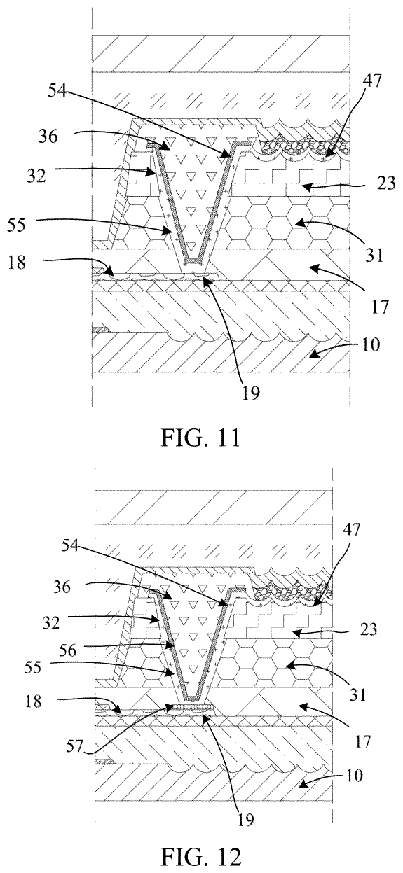

FIG. 11 is a schematic cross-sectional view of yet another display substrate of the present exemplary embodiment. In some exemplary embodiments, as shown in FIG. 11, the drive circuit assembly 18 includes a connection electrode 19. A first electrode unit 47 of the first electrode layer 34 is electrically connected to the connection electrode 19 by a via 32. The first electrode layer 34 may be provided with an opaque light shielding layer 54 corresponding to the via 32, so as to block the light directly irradiated toward the glass base substrate 10 from the via 32, and prevent the white light directly irradiated toward the glass base substrate 10 from the via 32 from mixing with light with other colors through the light filter 31. The light shielding layer 54 may be a high-reflectivity metal film. The first electrode unit 47 includes a via connection portion 55 located within the via 32. The via connection portion 55 overlays a hole wall of the via 32. The light shielding layer 54 overlays the via 32. The light shielding layer 54 of this example may overlay an end face of the via connection portion 55 away from the connection electrode 19.

FIG. 12 is a schematic cross-sectional view of another display substrate of the present exemplary embodiment. In some exemplary embodiments, as shown in FIG. 12, the drive circuit assembly 18 includes a connection electrode 19. A first electrode unit 47 of the first electrode layer 34 is electrically connected to the connection electrode 19 by a via 32. The first electrode layer 34 and the connection electrode 19 may be provided with an opaque light shielding layer 54 corresponding to the via 32, so as to block light directly irradiated toward the glass base substrate 10 from the via 32, and prevent the white light directly irradiated toward the glass base substrate 10 from the via 32 from mixing with light with other colors through the light filter 31. The light shielding layer 54 may be a high-reflectivity metal film. The light shielding layer 54 includes a first light shielding portion 56 and a second light shielding portion 57. The first electrode unit 47 includes a via connection portion 55 located in the via 32. The via connection portion 55 overlays a hole wall of the via 32. The first light shielding portion 56 may overlay an end face of the via connection portion 55 away from the connection electrode 19, and the second light shielding portion 57 may overlay an end face of the connection electrode 19 facing the via 32.

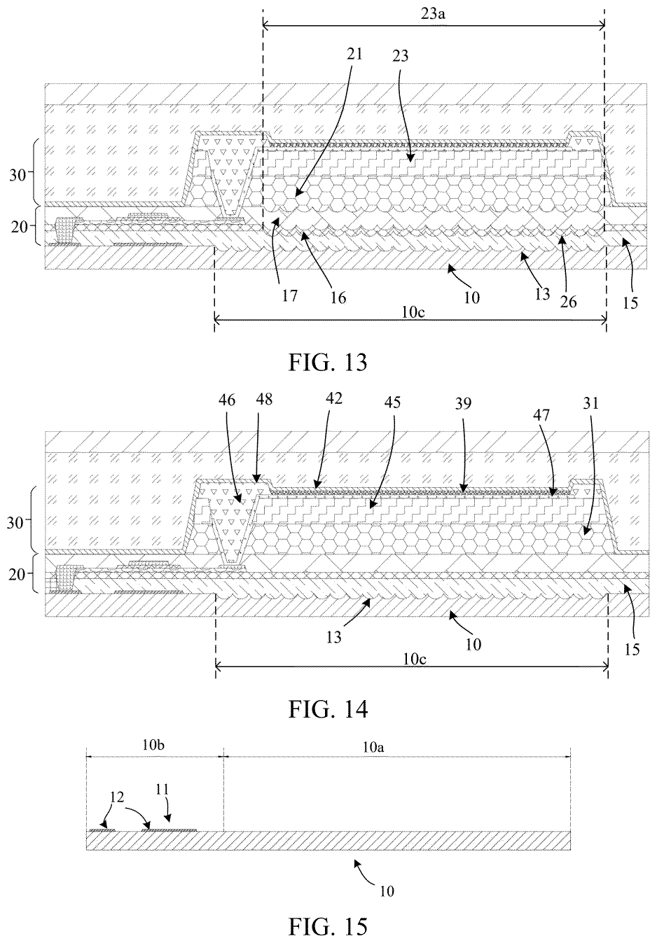

FIG. 13 is a schematic cross-sectional view of yet another display substrate of the present exemplary embodiment. In some exemplary embodiments, as shown in FIG. 13, the display substrate may include a glass base substrate 10, and a composite layer 15 and a planarization layer 23 stacked in a direction facing away from the glass base substrate 10. The glass base substrate 10 may include a first lens region 10c at an end face close to the composite layer 15. A plurality of first microlenses 13 are arranged in an array to form a microlens array. The planarization layer 23 is not provided with a microlens array. The composite layer 15 may include a second lens region 23a at an end face away from the glass base substrate 10. A plurality of second microlenses 26 are arranged in the second lens region 23a. The plurality of second microlenses 26 are arranged in an array to form a microlens array. An orthographic projection of the second lens region 23a on the glass base substrate 10 is configured to at least partially overlap the first lens region 10c. Therefore, the display substrate has a two-layer microlens array, so that more light can be emitted from the display substrate, the brightness of the display substrate can be improved, the luminous efficiency can be improved, and the power consumption can be reduced when the preset light intensity is reached.

FIG. 14 is a schematic cross-sectional view of another display substrate of the present exemplary embodiment. In some exemplary embodiments, as shown in FIG. 14, the display substrate may include a glass base substrate 10. The glass base substrate 10 may include a first lens region 10c at an end face close to the composite layer 15, and a plurality of first microlenses 13 are arranged in an array to form a microlens array, whereby the display substrate has a layer of microlens array. A first groove 48 enclosed by the second electrode layer 43 also provides a mounting space for the light emitting member 31, the first electrode unit 47, the planarization unit 45, and the light filter 31, and separates each of adjacent light emitting members 31, adjacent first electrode units 47, adjacent planarization units 45, and adjacent light filters 31. The light emitted by the light emitting member 39 is filtered by the light filter 31 and then irradiated toward the glass base substrate 10 through the notch of the first groove 48, and the second electrode layer 43 forms a reflection structure. The reflection structure can reflect the large-angle light emitted by the sub-pixels, so that the light can be converged, and the light extraction efficiency is improved.

In an exemplary embodiment, a manufacturing process of the display substrate as shown in FIGS. 5 and 6 may include the following operations.

### (1) Forming a Plurality of First Microlenses on a Glass Base Substrate.

FIG. 15 is a schematic diagram of a first preparation of the display substrate in FIG. 5. In some exemplary embodiments, as shown in FIGS. 5 to 8 and 15, forming a plurality of first microlenses on a glass base substrate may include first forming a shielding layer pattern 11 on the glass base substrate 10, and then etching to form the first microlenses 13 on the glass base substrate 10.

In some exemplary embodiments, a surface of the glass base substrate 10 facing the light emitting structure layer 30 includes a light emitting region 10a and a circuit region 10b, and the light emitting region 10a in turn includes a first lens region 10c. The shielding layer pattern 11 includes a first metal layer 12 overlaid on a surface of the glass base substrate 10. The circuit region 10b is at least partially overlaid by the first metal layer 12, and the first metal layer 12 may be an alloy made of copper (Cu), aluminum (Al), silver (Ag), titanium (Ti), molybdenum (Mo) or a low-resistance metal. A part of the first metal layer 12 may be a light shielding plate, which may block light from emitting, and another part of the first metal layer 12 may be SD or VDD wiring. A plurality of light emitting regions 10a may be provided and the circuit region 10b may separate the plurality of light emitting regions 10a.

In some exemplary embodiments, forming the shielding layer pattern 11 includes first depositing a first metal thin film on the glass base substrate 10, then coating a photoresist on the first metal thin film, pre-drying and then using a first mask template to expose the photoresist pattern through ultraviolet light, only retaining the photoresist pattern at the position of the first metal layer 12 after development, and then post-drying, etching, and peeling the photoresist to obtain the shielding layer pattern 11.

In some exemplary embodiments, a plurality of first microlenses 13 are uniformly arranged in the first lens region 10c, and the plurality of first microlenses 13 are arranged in an array to form a microlens array. A first microlens 13 may be a first arc-shaped surface 14 recessed on a surface of the glass base substrate 10 facing the light emitting structure layer 30, and the first arc-shaped surface 14 may be recessed toward a surface of the glass base substrate 10 away from the light emitting structure layer 30, forming an arc-shaped groove structure. A height of the first arc-shaped surface 14 may be set to a maximum distance H1 between the first arc-shaped surface 14 and a surface of the glass base substrate 10 facing the light emitting structure layer 30. The value of H1 may be 0.5 μm to 25 μm. In some exemplary embodiments, a cross section of the first arc-shaped surface 14 in a direction parallel to the glass base substrate 10 is circular. The maximum diameter of the cross section of the first arc-shaped surface 14 in the direction parallel to the glass base substrate 10 may be D1. The value of D1 may be 1 μm to 50 μm. A plurality of light emitting regions 10a are provided, and the size and arrangement of the first microlenses 13 in the plurality of light emitting regions 10a may be consistent.

In some exemplary embodiments, the first microlenses 13 may be etched on the glass base substrate 10 by wet etching, or by dry etching, in this case by wet etching. In an etching process, part of the glass material on the glass base substrate 10 may be removed using an etching solution of the HF series to form a recessed first arc-shaped surface 14, as shown in FIG. 5. But not limited to this, for example, dry etching is used. In the etching process, the etching gas uses F-series CF4 (carbon tetrafluoride) gas or SF6 (sulfur hexafluoride) gas to cooperate with etching, and part of the glass material on the glass base substrate 10 is removed to form a recessed first arc-shaped surface 14.

### (2) Forming a Drive Circuit Layer.

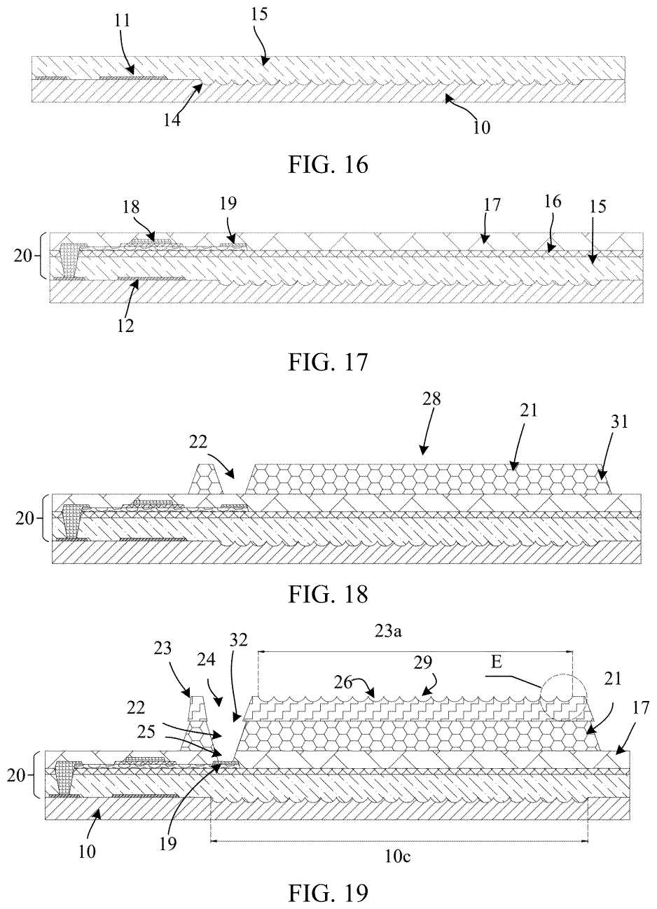

FIG. 16 is a schematic diagram of a second preparation of the display substrate in FIG. 5, and FIG. 17 is a schematic diagram of a third preparation of the display substrate in FIG. 5. In some exemplary embodiments, as shown in FIGS. 16 and 17, forming a drive circuit layer 20 includes first forming a composite layer 15, and then preparing a first buffer layer 16, an interlayer insulating layer (ILD/PVX) 17, and a drive circuit assembly 18 by a process such as deposition and etching to form a drive circuit layer 20. The drive circuit layer 20 is overlaid on the glass base substrate 10.

In some exemplary embodiments, the drive circuit layer 20 includes a composite layer 15, a first buffer layer 16, an interlayer insulating layer (ILD/PVX) 17 which are stacked. The first buffer layer 16 is overlaid on a side of the composite layer 15 away from the glass base substrate 10. The interlayer insulating layer (ILD/PVX) 17 is located on a side of the first buffer layer 16 away from the composite layer 15. The drive circuit assembly 18 is connected to a first metal layer 12 by a via structure. The drive circuit assembly 18 includes a connection electrode 19, which may be made of an opaque metal material.

In some exemplary embodiments, first forming the composite layer may include uniformly coating a liquid solvent containing a dielectric material on a glass base substrate 10 having the first microlenses 13 by Spin on Glass (SOG), and then curing to form the composite layer by heat treatment. During the coating of the liquid solvent, an arc-shaped groove formed by the recess of the first arc-shaped surface 14 can be filled.

In some exemplary embodiments, the material of the composite layer 15 may be an organic-inorganic mixed resin containing silicon (Si), oxygen (O), and nitrogen (N), and the organic-inorganic mixed resin has good heat resistance and can withstand high temperatures from 300° C. to 500° C. The composite layer 15 is a mixture of inorganic and organic materials, so that the composite layer 15 has the functions of a planarization layer and a buffer layer at the same time. A refractive index of the composite layer 15 may be from 1.5 to 2.0, and the refractive index of the composite layer 15 may be changed by adjusting the ratio of the content of oxygen (O) and nitrogen (N) in the organic-inorganic mixed resin, and the refractive index of the composite layer 15 is greater than that of the glass base substrate 10. A plane of the composite layer 15 away from the glass base substrate 10 is parallel to the glass base substrate 10, and protruding portions of a surface of the composite layer 15 close to the glass base substrate 10 fill arc-shaped grooves formed by the recesses of the first arc-shaped surface 14.

### (3) Forming a Plurality of Second Microlenses on a Planarization Layer.

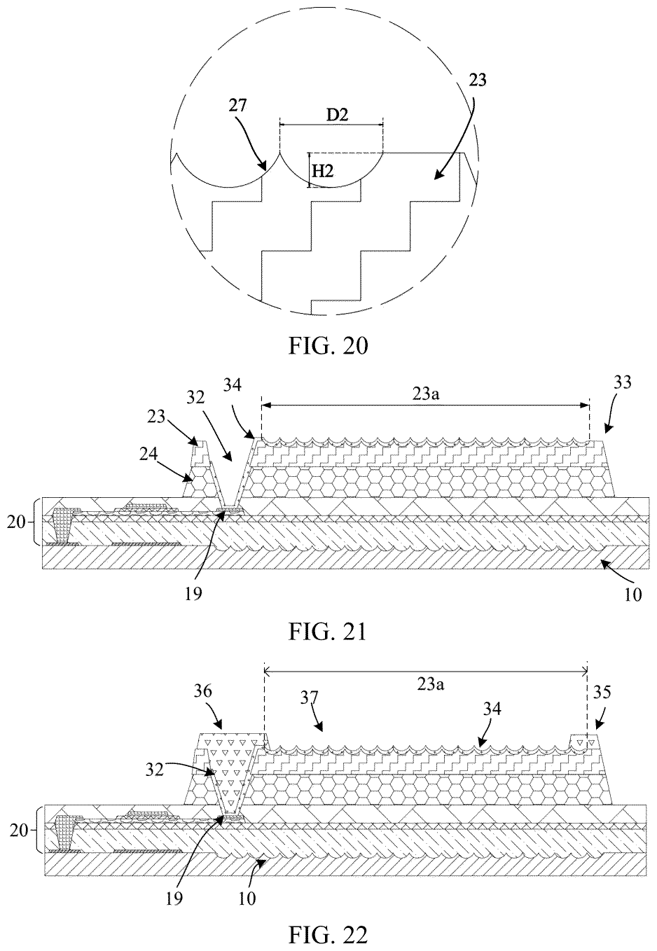

FIG. 18 is a schematic diagram of a fourth preparation of the display substrate in FIG. 5, FIG. 19 is a schematic diagram of a fifth preparation of the display substrate in FIG. 5, and FIG. 20 is a partially enlarged schematic diagram at E in FIG. 19. In some exemplary embodiments, as shown in FIGS. 18 to 20, forming the first microlenses may include first forming a light filter layer pattern 28 on the drive circuit layer 20, forming a planarization layer pattern 29, and etching the second microlenses 26.

In some exemplary embodiments, forming the light filter layer pattern 28 on the drive circuit layer 20 includes first depositing a layer of color light film on the drive circuit layer 20, and then forming the light filter layer 21 by etching to obtain the light filter layer pattern 28. The light filter layer pattern 28 includes a light filter layer 21 overlaid on the drive circuit layer 20. An orthographic projection of the light filter layer 21 on the glass base substrate 10 is located in the light emitting region. The light filter layer 21 may include a plurality of light filters 31 arranged at intervals on a plane parallel to the glass base substrate 10, and the light filters 31 are forming by etching the color light film. The light filter layer 21 may filter light, filtering white light into light of a preset color, and the light filter layer 21 may be a red light filter, a green light filter, or a blue light filter. The light filter layer 21 has a first through hole 22 that penetrates through the light filter layer 21 in a direction perpendicular to the glass base substrate 10.

In some exemplary embodiments, forming a planarization layer pattern 29 includes coating an organic material layer, and then forming a planarization layer 23 by etching to obtain a planarization layer pattern 29. The light filter layer pattern 28 includes a planarization layer 23 disposed on the light filter layer pattern 28, and the planarization layer 23 completely overlays an end face of the light filter layer 21 away from the drive circuit layer 20. The planarization layer 23 is provided with a second through hole 24. The second through hole 24 penetrates through the planarization layer 23 in a direction perpendicular to the glass base substrate 10, and the second through hole 24 and the first through hole 22 are correspondingly communicated. In addition, the interlayer insulating layer (ILD/PVX) 17 is provided with a third through hole 25 on an end face close to the planarization layer 23. One end of the third through hole 25 communicates with the second through hole 24, and the other end of the third through hole 25 extends to the connection electrode 19, whereby the first through hole 22, the second through hole 24, and the third through hole 25 form a via 32 extending in a direction perpendicular to the glass base substrate 10.

In some exemplary embodiments, etching the second microlenses 26 may employ dry etching to remove part of the material on the planarization layer 23 to form recessed second microlenses 26. A surface of the planarization layer 23 away from the glass base substrate 10 may include a second lens region 23a. An orthographic projection of the second lens region 23a on the glass base substrate 10 is located within the first lens region 10c. The planarization layer 23 may have a plurality of second lens regions 23a. The second lens regions 23a and the first lens regions 10c are in one-to-one correspondence. A plurality of second microlenses 26 are uniformly arranged in the second lens region 23a, and the plurality of second microlenses 26 are arranged in an array to form a microlens array. A second microlens 26 may be a second arc-shaped surface 27 recessed on a surface of the planarization layer 23 away from the glass base substrate 10, and the second arc-shaped surface 27 may be recessed toward a surface of the planarization layer 23 away from the light emitting structure layer 30, forming an arc-shaped groove structure. The height of the second arc-shaped surface 27 may be set to a maximum distance H2 between the second arc-shaped surface 27 and a surface of the planarization layer 23 facing the light emitting structure layer 30, and the value of H2 may be 0.5 μm to 25 μm. In some exemplary embodiments, a cross section of the second arc-shaped surface 27 in a direction parallel to the glass base substrate 10 is circular. The maximum diameter of the cross section of the second arc-shaped surface 27 in a direction parallel to the glass base substrate 10 may be D2, and the value of D2 may be 1 μm to 50 μm. In addition, the structures, sizes, and arrangements of the second arc-shaped surface 27 and the first arc-shaped surface 14 are consistent, but not limited to this. For example, the second arc-shaped surface 27 and the first arc-shaped surface 14 are inconsistent in at least one of the structure, size, and arrangement.

### (4) Forming a Light Emitting Structure Layer.

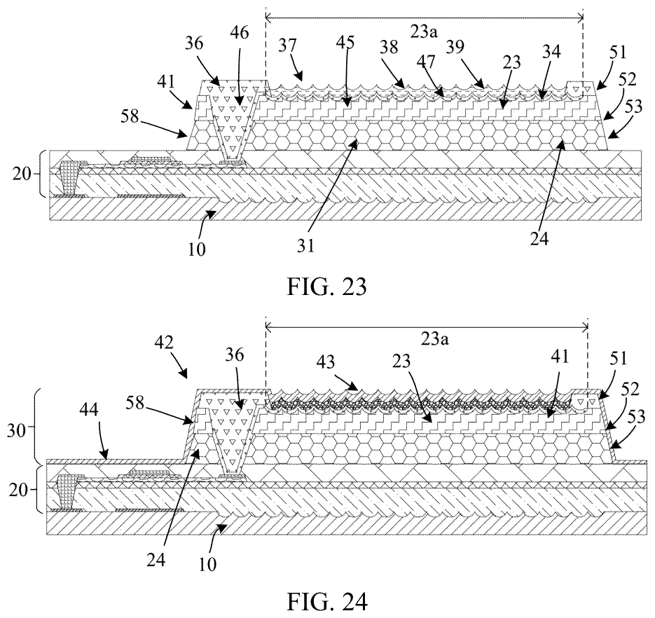

FIG. 21 is a schematic diagram of a sixth preparation of the display substrate in FIG. 5, FIG. 22 is a schematic diagram of a seventh preparation of the display substrate in FIG. 5, FIG. 23 is a schematic diagram of an eighth preparation of the display substrate in FIG. 5, and FIG. 24 is a schematic diagram of a ninth preparation of the display substrate in FIG. 5. In some exemplary embodiments, as shown in FIGS. 21 to 24, forming a light emitting structure layer may include forming a first electrode pattern 33, forming a pixel definition layer pattern 35, forming a light emitting layer 38, and forming a second electrode layer 42.

In some exemplary embodiments, as shown in FIGS. 20 and 21, forming the first electrode pattern 33 includes first depositing a layer of electrode thin film on a planarization layer pattern 29 on which a second microlens 26 is etched, and then etching the electrode thin film to form a first electrode pattern 33. The first electrode pattern 33 includes a light filter layer 24 and a planarization layer 23 which are stacked, and a first electrode layer 34. The first electrode layer 34 overlays the second lens region 23a on the planarization layer 23 and extends into a via 32 and is attached to the connecting electrodes 19 to form a connection between the first electrode layer 34 and the via 32 of the drive circuit. The first electrode layer 34 may be used as an anode, the first electrode layer 34 may be a light-transmitting electrode for allowing light to penetrate, and the connection electrode 19 and/or the first electrode layer 34 may be provided with an opaque structure to prevent light from directly transmitting through the first electrode layer 34 at the via 32 and then continuing to irradiate in a direction toward the glass base substrate 10. The first electrode layer 34 may overlay all of hole walls of the via 32, or only part of the hole walls of the via 32.

In some exemplary embodiments, as shown in FIGS. 21 and 22, forming the pixel definition layer pattern 35 includes first depositing a layer of inorganic material film on the first electrode pattern 33, and then forming the pixel definition layer pattern 35 by etching. The pixel definition layer pattern 35 includes a pixel definition layer 36 overlaying the first electrode pattern 33, and the pixel definition layer 36 is provided with a pixel opening 37 that exposes the first electrode layer 34. The pixel definition layer 36 is located on a side of the first electrode layer 34 away from the glass base substrate 10, and part of the pixel definition layer 36 fills the vacancy of the via 32. A plurality of pixel openings 37 are provided and the plurality of pixel openings 37 are arranged in an array. The pixel definition layer 36 may be made of a high transmittance material, so that the pixel definition layer 36 has a high transparency, and more light can pass through the pixel definition layer 36.

In some exemplary embodiments, as shown in FIGS. 22 and 23, the light emitting layer 38 may be formed by evaporation deposition to prepare the light emitting layer 38 within the pixel opening 37. The light emitting layer 38 overlays a bare end face portion of the first electrode layer 34 facing away from the glass base substrate 10. The light emitting layer 38 includes a plurality of light emitting members 39. The plurality of light emitting members 39 and the plurality of pixel openings 37 are in one-to-one correspondence. The light emitting members 39 are each arranged in the respective corresponding pixel opening 37 and located on a side of the first electrode layer 34 away from the glass base substrate 10. An orthographic projection of the plurality of light emitting members 39 on the glass base substrate 10 is located within an orthographic projection range of the second lens region 23a on the glass base substrate 10. The light emitting member 39 may emit white light when powered.

In some exemplary embodiments, as shown in FIGS. 21 to 24, the light filter 31, the planarization unit 45, the first electrode unit 47, the pixel defining unit 46, and the light emitting member 39 constitute a first member 41 that overlays a portion in an end face of the drive circuit layer 20 away from the glass base substrate 10. In the first member 41, the planarization unit 45 has a recessed second arc-shaped surface 27. The first electrode unit 47 is filled in a groove structure formed by the second arc-shaped surface 27, and the light emitting member 39 is overlaid on the first electrode unit 47, so that the portions of the light emitting layer 38 and the first electrode layer 34 corresponding to the second lens region 23a in a direction perpendicular to the glass base substrate 10 are wavy, rather than parallel to the glass base substrate 10. In the first member 41, in a direction parallel to the glass base substrate 10, an end face of the first member 41 in a circumferential direction is a fourth end face 58. An end face of the light filter 31 in a direction parallel to the glass base substrate 10 is a third end face 53. An end face of the planarization unit 45 in the direction parallel to the glass base substrate 10 is a second end face 52. An end face of the pixel defining unit 46 in the direction parallel to the glass base substrate 10 and away from the pixel opening 37 is a first end face 51. The fourth end face 58 is composed of a first end face 51, a second end face 52, and a third end face 53 sequentially arranged in the direction perpendicular to the glass base substrate 10. The first member 41, the drive circuit layer 20 and the glass base substrate 10 constitute an intermediate blank.

In some exemplary embodiments, as shown in FIGS. 21 to 24, forming a second electrode layer 42 includes depositing a layer of electrode thin film on an intermediate blank formed by the first member 41, the drive circuit layer 20, and the glass base substrate 10, constituting the second electrode layer 42. The second electrode layer 42 overlays a surface of an outer surface of the first member 41 away from the drive circuit layer 20, and a fourth end face 58. The second electrode layer 42 also overlays a portion of a end face of the drive circuit layer 20 away from the glass base substrate 10 that is not overlaid by the first member 41. The second electrode layer 42 may serve as a cathode. The plurality of light emitting members 39 share one cathode. The second electrode layer 42 may be made of a high reflectivity metal such that the second electrode layer 42 may reflect the light irradiated thereon by the light emitting member 39 toward the glass base substrate 10.

### (5) Forming an Encapsulation Structure.

In some exemplary embodiments, as shown in FIGS. 5 and 6, forming the encapsulation structure layer 40 may include preparing an encapsulation film 43 on the light emitting structure layer 30, and mounting a cover plate 44 on a side of the encapsulation film 43 away from the glass base substrate 10. The encapsulation film 43 may be one or more layers of inorganic or organic thin films. The encapsulation film 43 overlays an end face of the light emitting structure layer 30 away from the glass base substrate 10 by Thin Film Encapsulation (TFE) technology. The encapsulation film 43 can prevent water and oxygen from entering the display substrate, providing a good water-oxygen isolation characteristic for the display substrate. The cover plate 44 is overlaid on a side of the encapsulation film away from the glass base substrate 10. The cover plate 44 can provide protection for the display substrate.

The present disclosure also provides a display apparatus which can include the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although the implementations of the present disclosure are disclosed above, the contents are only implementations used for ease of understanding of the present disclosure, but not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display substrate comprising a glass base substrate and a composite layer and a planarization layer disposed in a direction facing away from the glass base substrate;
wherein the glass base substrate comprises a first lens region at an end face close to the composite layer, and the composite layer and/or the planarization layer comprises a second lens region at an end face away from the glass base substrate; and
an orthographic projection of the second lens region on the glass base substrate at least partially overlaps an orthographic projection of the first lens region on the glass base substrate.

2. The display substrate of claim 1, wherein a plurality of first microlenses are arranged in the first lens region, and a first microlens is provided as a first arc-shaped surface recessed toward a side of the glass base substrate away from the composite layer; and
a plurality of second microlenses are arranged in the second lens region, and a second microlens is provided as a second arc-shaped surface recessed toward the glass base substrate.

3. The display substrate of claim 2, wherein at least one of the first microlenses and the second microlenses has the same structure and size.

4. The display substrate of claim 2, wherein the composite layer is made of an inorganic-organic mixed resin having a refractive index of 1.5 to 1.9.

5. The display substrate of claim 2, wherein a diameter of a cross section of the first arc-shaped surface in a direction parallel to the glass base substrate is set to be from 1 micron to 50 microns; and
the first arc-shaped surface is set to have a maximum size of 0.5 microns to 25 microns in a direction perpendicular to the glass base substrate.

6. The display substrate of claim 2, further comprising a light filter layer arranged to overlay an end face of the planarization layer close to the glass base substrate, wherein a refractive index of the planarization layer is set to be greater than a refractive index of the light filter layer; and
wherein a refractive index of the composite layer is set to be greater than a refractive index of the glass base substrate.

7. The display substrate of claim 1, further comprising a first electrode layer, a pixel definition layer, a light emitting layer, and a second electrode layer;
wherein the first electrode layer, the light emitting layer and the second electrode layer are stacked in sequence in a direction away from the glass base substrate, the first electrode layer is located on a side of the planarization layer away from the glass base substrate, and the first electrode layer is provided as a light-transmitting electrode;
the pixel definition layer encloses a plurality of pixel openings, and the light emitting layer is located within the pixel openings; and
the second electrode layer is configured to reflect light passing through the pixel definition layer toward the glass base substrate.

8. The display substrate of claim 7, wherein an orthographic projection of the pixel definition layer on the glass base substrate at least overlaps an orthographic projection of the first lens region or/and the second lens region on the glass base substrate.

9. The display substrate of claim 7, wherein the second electrode layer is configured to enclose a plurality of first grooves with notches facing the glass base substrate;
wherein the pixel definition layer comprises a plurality of pixel defining units arranged at intervals in a direction parallel to the glass base substrate, the plurality of pixel defining units each enclosing a pixel opening; the light emitting layer comprises a plurality of light emitting members, and the light emitting members and the pixel defining units are arranged in one-to-one correspondence and are both located within the first grooves.

10. The display substrate of claim 9, wherein the planarization layer comprises a plurality of planarization units, the plurality of planarization units are arranged in one-to-one correspondence with the plurality of pixel defining units and located within the first grooves, and the plurality of planarization units are each provided with the second lens region on a side away from the glass base substrate.

11. The display substrate of claim 10, further comprising a light filter layer on a side of the planarization layer close to the glass base substrate;
wherein the light filter layer comprises a plurality of light filters arranged at intervals in a direction parallel to the glass base substrate, and the light filters are arranged in one-to-one correspondence with the pixel defining units and located in the first grooves.

12. The display substrate of claim 11, wherein a plurality of first lens regions are provided, the light filters are arranged in one-to-one correspondence with the first lens regions, and an orthographic projection of the first lens regions on the glass base substrate is located within an orthographic projection of the light filters on the glass base substrate.

13. The display substrate of claim 11, further comprising a drive circuit layer located between the glass base substrate and the first electrode layer;
wherein the second electrode layer comprises groove portions and overlay portions arranged alternately in a direction parallel to the glass base substrate, the groove portions are each arranged in a groove shape, the groove portions enclose the first grooves, and the overlay portions are overlaid on a surface of the drive circuit layer away from the glass base substrate.

14. The display substrate of claim 13, wherein the groove portions each comprise a groove side wall and a groove bottom wall, the groove side wall being configured to be annular in a direction parallel to the glass base substrate, and the groove bottom wall being arranged to close an end of the groove side wall away from the glass base substrate;
a circumferential surface of a pixel defining unit in a direction parallel to the glass base substrate is provided as a first end face;
a circumferential surface of a planarization unit in the direction parallel to the glass base substrate is provided as a second end face;
a circumferential surface of a light filter in the direction parallel to the glass base substrate is provided as a third end face;
the first end face, the second end face and the third end face are configured to be arranged sequentially in a direction perpendicular to the glass base substrate;
the groove side wall is configured to overlay the first end face, the second end face and the third end face; and
the groove bottom wall is configured to overlay end faces of the pixel defining unit and the light emitting members away from the glass base substrate.

15. The display substrate of claim 11, further comprising a drive circuit assembly and a light shielding layer, wherein the drive circuit assembly is located between the planarization layer and the composite layer;
the first electrode layer comprises a plurality of first electrode units, the first electrode units being arranged in the first grooves;
the drive circuit assembly comprises a connection electrode, and a first electrode unit connects the connection electrode through a via; and
the light shielding layer is provided as a high reflectivity metal film, and the light shielding layer is located on the first electrode layer and/or the connection electrode and arranged corresponding to the via to block light directly irradiated toward the glass base substrate from the via.

16. The display substrate of claim 15, wherein the light shielding layer is configured to overlay an end face of the connection electrode facing the via, and an orthographic projection of the light shielding layer on the glass base substrate is configured to at least partially overlap an orthographic projection of the via on the glass base substrate.

17. The display substrate of claim 15, wherein the first electrode unit comprises a via connection portion located within the via, and the light shielding layer is configured to overlay an end face of the via connection portion away from the glass base substrate.

18. The display substrate of claim 15, wherein the via is configured to penetrate through the planarization layer and the light filter layer, the first electrode unit is configured to overlay at least a portion of a hole wall of the via, and the pixel definition layer extends into the via.

19. A preparation method applied to the display substrate of claim 1, comprising:
forming a plurality of first microlenses on the glass base substrate, wherein the plurality of first microlenses are arranged in the first lens region, and a first microlens is provided as a first arc-shaped surface recessed toward an end face of the glass base substrate away from the composite layer; and
forming a plurality of second microlenses on the composite layer and/or the planarization layer, wherein the plurality of second microlenses are arranged in the second lens region, and a second microlens is provided as a second arc-shaped surface recessed towards the glass base substrate.

20. A display apparatus, comprising the display substrate of claim 1.
